(19) United States
(12) Patent Application Publication
(10) Pub. No.: US 2002/0168847 A1
(43) Pub. Date: Nov. 14, 2002

(54) Methods of forming a nitridated surface on a metallic layer and products produced thereby

(75) Inventors: Pravin Narwankar, Sunnyvale, CA (US); Ravi Rajagopalan, Sunnyvale, CA (US); Turgut Sahin, Cupertino, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/852,440

(22) Filed: May 9, 2001

(51) Int. Cl. H01L 21/4763; H01L 21/31; H01L 21/469

(52) U.S. Cl. 438/635; 438/765; 438/768

(57) ABSTRACT

A method of providing a stable interface between a metallic layer and a dielectric layer in a semiconductor device is provided. The method includes generating a remote nitrogen containing plasma and flowing activated nitrogen species, from the remote site to the location of the metallic layer. The activated nitrogen species are flowed over at least the surface of the metallic layer, where they react with the metallic surface to form a metal nitride. The treated layer can be used to provide a stable bottom electrode in a capacitor stack formation.

### FIELD OF THE INVENTION

The present invention relates generally to a method of forming a nitridated surface on an electrically conductive film or layer for use in the semiconductor arts, and products resulting therefrom.

### BACKGROUND OF THE INVENTION

The reliable operation of integrated circuits is critically dependent on the reliability of the increasingly thin dielectric layers used in circuit devices. As transistors have become smaller and more densely packed, the dielectrics have become thinner.

Capacitor and gate dielectrics are often less than 80 angstroms in thickness, sometimes approaching 50 angstroms or less. For integrated circuits to work, these thin layers in each of thousands of different transistors must provide sufficient capacitance to drive the device, protect the channel from migration of impurities and avoid production of charge traps at their interfaces. These demanding requirements may soon exceed the capacities of conventional silicon oxide layers. Silicon oxide layers less than 2 nm may have prohibitively large leakage currents.

Efforts to replace silicon oxide as the gate dielectric have thus far proved less than satisfactory. Because of its relatively low dielectric constant (approx. 3.9), the largest capacitance obtainable with a thin layer of silicon oxide is about 25 fF/μm². This limits the scaling of transistors to smaller sizes because the capacitance will not be sufficient to drive the device. Higher dielectric constant tantalum oxide has been tried, but results are poor due to a high density of charge traps at the dielectric/silicon interface. Composite layers of SiO₂/Ta₂O₅ and SiO₂/Ta₂O₅/SiO₂ were tried, but the necessary resulting thicknesses limit the capacitance which can be obtained. Efforts have also been made to deposit a thin layer of silicon nitride between the silicon and the tantalum oxide, to prevent interaction/reaction between the silicon and the Ta₂O₅, to prevent the formation of SiO₂.

Tantalum oxide or tantalum pentoxide, as it is sometimes referred to (Ta₂O₅) is generally accepted as the next material for use in memory capacitors. However, efforts to make capacitors using Ta₂O₅ films deposited by reactive sputtering, chemical vapor deposition (CVD), and plasma enhanced chemical vapor deposition have produced devices having high leakage currents and low breakdown voltages. One of the reasons for this is that the interfaces between the Ta₂O₅ films and conductive substrates are not stable. This phenomenon is evident with the use of metallic substrates. For example, peeling of Ta₂O₅ films from tungsten substrates has been observed, due to the formation of WO₃ at the tungsten/tantalum pentoxide interface, either during tantalum deposition at temperatures greater than about 425° C. or during the annealing of Ta₂O₅ when the annealing ambient is strongly oxidative. There remains a need to improve the stability of the interface between the metallic and dielectric layer.

Referring to FIG. 3, a schematic sectional representation of a front end DRAM/e-DRAM capacitor cell 100 is shown in which ruthenium (Ru) was employed for both the bottom 102 and top 106 electrodes. A film of Ta₂O₅ 104 was deposited over the bottom electrode 102 as the dielectric in this stack. However, during the deposition and anneal of the Ta₂O₅ layer 104, the ruthenium in the bottom electrode 102 may become at least partially oxidized (i.e., transformed to RuO₂). Although RuO₂ is electrically conductive, the transformation causes a resultant volume increase which can develop sharp features in the surface of the bottom electrode 102 and this may cause either shorting of the capacitor or unacceptably high amounts of current leakage. Further, the deposition of a top ruthenium electrode can result in a similar oxidation layer of RuO₂ at the interface with the dielectric, and oxygen scavenging from the dielectric layer can also occur.

Similarly, tungsten (W) has been attempted for use in a bottom electrode of a structure similar to that shown in FIG. 3. Oxidation of the tungsten electrode can also occur during the deposition and anneal of the Ta₂O₅ layer thereover, to transform at least some of the tungsten to WO₃. Unfortunately, WO₃ is volatile, and this seriously effects the performance of the resultant capacitor.

Similar problems are observed when tantalum oxide is used as a dielectric that interfaces with conductors in other devices, such as RF capacitors, for example. RF capacitors are primarily used as passive elements in filtering networks for high frequency communication devices. These types of capacitors are large (e.g., at least 100 microns×100 microns) planar structures. In one example, where titanium nitride conductors interface with a tantalum oxide dielectric, the interfaces between dielectric and conductor exhibit some oxidation of the conductor, oxygen scavenging of the dielectric, and intermixing/migration of species between the dielectric and conductor.

As such, there is a need for a new method for making tantalum oxide thin film capacitors having a high dielectric constant that will not degrade due to high temperatures during the annealing process, and which will maintain acceptable stability at the interface between the tantalum oxide and the substrate after processing and during use.

### SUMMARY OF THE INVENTION

An embodiment of the present invention provides a method of treating an electrically conductive surface to be used in making a stable conductor/dielectric interface, which includes providing a conductive substrate having a surface in a treatment chamber; generating a nitrogen containing plasma in a cavity remote from the treatment chamber; flowing a nitrogen reactive species created from the nitrogen containing plasma into the treatment chamber and over the surface of the conductive substrate; and allowing the nitrogen reactive species to react with the surface of the conductive substrate to transform at least a portion of the surface into a nitride composition.

Specific examples include a substrate comprising tungsten, where the surface is transformed into tungsten nitride. Such a substrate acts to form a stable interface with a dielectric material that is deposited over it. Other surface layers to be treated may comprise tungsten nitride, tantalum nitride, tantalum, titanium nitride, or the like.

A method of forming a metal/dielectric stack structure is described as including the steps of depositing a metal layer on a substrate; generating a nitrogen containing plasma in a cavity remote from a treatment chamber in which the metal layer resides; flowing a nitrogen reactive species created from the nitrogen containing plasma into the treatment chamber and over a surface of the metal layer, thereby reacting the nitrogen reactive species on the surface to form a nitridated surface; and depositing a dielectric layer over the nitridated surface.

The metal layer which is deposited can be a tungsten film, a tungsten nitride film, a tantalum film, a tantalum nitride film or a titanium nitride film, for example. The nitrogen containing plasma may be generated from N₂ or NH₃, for example.

When the metallic layer is tungsten, a method of nitriding the surface to form tungsten nitride includes providing a tungsten substrate in a reaction chamber; generating a nitrogen containing plasma in a cavity remote from the reaction chamber; and flowing a nitrogen reactive species created from the nitrogen containing plasma into the reaction chamber and over the surface of a heated tungsten substrate, thereby reacting the nitrogen reactive species on the surface to form a tungsten nitride surface.

This process is useful in the semiconductor arts, for example, where the tungsten substrate comprises a tungsten layer which has been deposited over a substrate such as a silicon wafer, for example.

A capacitor forming method is described to include depositing an electrically conductive film on a substrate, thereby forming a bottom electrode; generating a nitrogen containing plasma in a cavity remote from the bottom electrode; and flowing a nitrogen reactive species, created from the nitrogen containing plasma, over at least a surface of the bottom electrode, thereby reacting the nitrogen reactive species with the surface of the electrically conductive film to form a nitridated surface, or to enhance the nitrogen content at the surface.

Further, a dielectric layer may next be deposited over the treated bottom electrode. Among other dielectric materials, a dielectric material comprising Ta₂O₅ will form a stable interface with such a bottom electrode, during Ta₂O₅ deposition or during post deposition oxidation anneal.

Products resultant from the above-mentioned processes are also disclosed, including a metallic layer deposited on a substrate in a semiconductor device, wherein the metallic layer may be selected from tungsten, tungsten nitrides, tantalum, tantalum nitrides and titanium nitrides, for example, and wherein the metallic layer is further nitridated by a remote plasma process.

A capacitor structure in a semiconductor device is described to include a substrate; a bottom electrode deposited on the substrate; a dielectric layer deposited over a nitridated surface of the bottom electrode; and a top electrode deposited over the dielectric layer.

The dielectric layer may be Ta₂O₅, for example. Optionally, a barrier layer may be deposited on a top surface of the dielectric layer and underlying the top electrode, and this option may be used depending upon the composition of the dielectric layer.

These and other objects, advantages, and features of the invention will become apparent to those persons skilled in the art upon reading the details of the process and products as more fully described below.

### BRIEF DESCRIPTION OF THE DRAWINGS

FIG. 1 is a schematic representation of an anneal chamber including a remote cavity for the remote generation of a plasma to carry out a processes according to the present invention.

FIG. 2 is a partial sectional diagram of a stack built up according to the present invention, to include a bottom electrode treated according to the present invention.

FIG. 3 is a schematic sectional representation of a known front end DRAM/eDRAM capacitor stack structure.

FIG. 4 is a schematic sectional representation of a front end DRAM/e-DRAM capacitor stack structure produced according to the present invention.

FIG. 5A is a graph which illustrates the relative atomic concentration of the various atomic species at indicated depths of a TaN electrode layer produced according to a known method.

FIG. 5B is a graph which illustrates the relative atomic concentration of the various atomic species at indicated depths of a TaN electrode layer produced according to another known method.

FIG. 5C is a graph which illustrates the relative atomic concentration of the various atomic species at indicated depths of a TaN electrode layer produced according to the present invention.

FIG. 6A is a graph which illustrates how leakage current varies for different electrode voltages at 100 Å depth for capacitors having bottom electrodes produced according to the methods described with regard to FIGS. 5A, 5B and 5C, respectively, with each arrangement having a TiN top electrode.

FIG. 6B is a graph which illustrates how leakage current varies for different electrode voltages at 150 Å depth for capacitors having bottom electrodes produced according to the methods described with regard to FIGS. 5A, 5B and 5C, respectively, with each arrangement having a TiN top electrode.

FIG. 6C is a graph which illustrates how leakage current varies for different electrode voltages at 200 Å depth for capacitors having bottom electrodes produced according to the methods described with regard to FIGS. 5A, 5B and 5C, respectively, with each arrangement having a TiN top electrode.

### DETAILED DESCRIPTION OF PREFERRED EMBODIMENTS

Before the present procedures and resultant products described, it is to be understood that this invention is not limited to any particular process, process step or material described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a”, “and”, and “the” include plural referents unless the context clearly dictates otherwise. Thus, for example, reference to “a substrate” includes a plurality of such substrates and reference to “the surface” includes reference to one or more surfaces and equivalents thereof known to those skilled in the art, and so forth.

The publications discussed herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed.

### Definitions

The term “substrate” broadly covers any object that is being processed in a process chamber. The term “substrate” includes, for example, semiconductor wafers, or portions or components thereon, flat panel displays, glass plates or disks, plastic work pieces or portions of any of the preceding, and the like.

The following abbreviations are used throughout the specification:

PVD is used for physical vapor deposition.

CVD is used for chemical vapor deposition.

PECVD is used for plasma enhanced chemical vapor deposition.

RPECVD is used for remote plasma enhanced chemical vapor deposition.

RTPCVD is used for rapid thermal processing chemical vapor deposition.

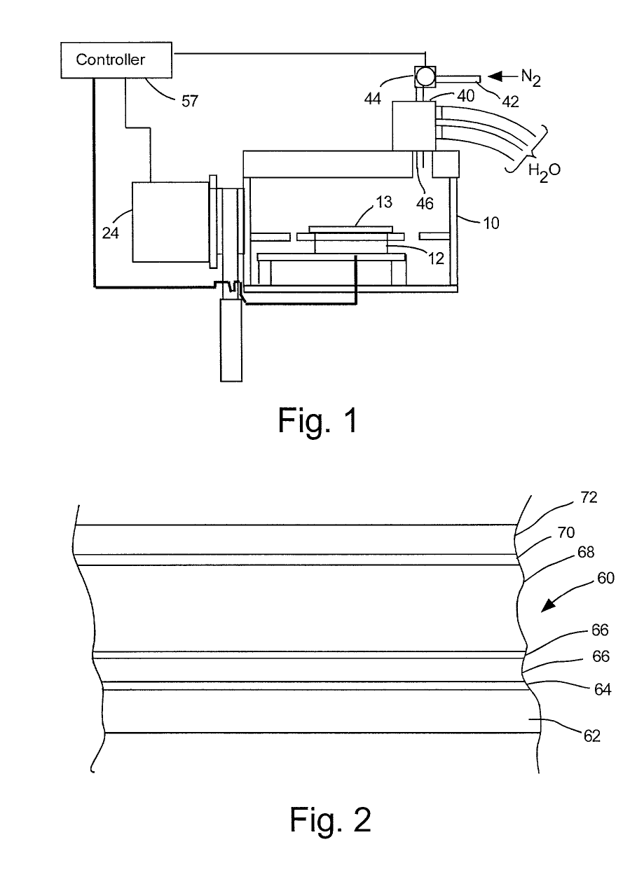

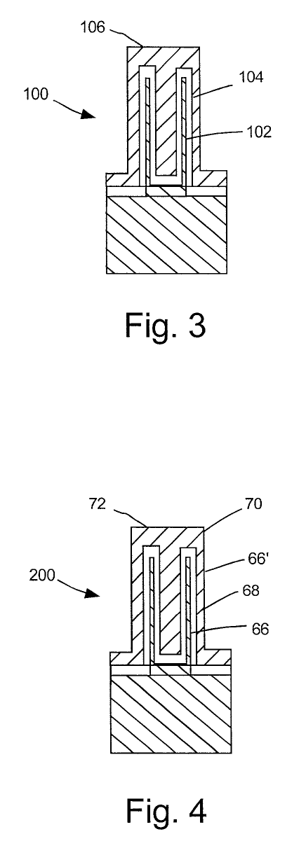

Referring now to FIG. 1, a chamber 10, which may be an anneal chamber, such as the Applied Materials XZ Anneal Chamber, for example, may be used in carrying out the present invention. It is noted that the present invention is not limited by the chamber described with regard to FIG. 1, but may be carried out in other chambers, including other CVD systems used with the Endura system manufactured and sold by Applied Materials, Inc. of Santa Clara, Calif., RTP chambers used with the Centura mainframe of Applied Materials, and other chambers including those used in PVD, CVD, PECVD, RPECVD and RTPCVD processes.

Chamber 10 is a vacuum tight chamber, and may be made of aluminum, for example. A susceptor 12 is situated in the chamber 10. Susceptor 12 may also be made of aluminum or ceramic, and functions to support a substrate 13 (e.g. a semiconductor wafer) during processing. The susceptor includes built in resistive heating, as is known in the art.

A vacuum pump system 24 is connected to the chamber 10 and produces and maintains the required vacuum conditions in the chamber for processing. A remote chamber 40, which may be water-cooled, is mounted to chamber 10, on top of chamber 10 in this example, although a side mount may also be possible. Chamber 40 is used to remotely excite or activate a corresponding process gas, e.g., by forming a plasma, prior to flowing the excited process gas into chamber 10 and over a layer having been previously deposited on substrate 13. Chamber 40 receives a nitrogen containing gas, such as NH₃ or N₂ through a supply line 42 that is controlled by a pulse valve 44, or other valve mechanism suitable for this purpose. The pulse valve 44 may be a solenoid or piezoelectric valve. Chamber 40 supplies activated species into chamber 10 through injection port 46, mounted through the lid of the chamber 10. Chamber 40 is used to generate a remote plasma with the inputted gas or gases, to activate the species before it is flown into the chamber 10.

In the described embodiment, the chamber 40 is a microwave generated plasma chamber, such as one produced by ASTEX, of Wilmington, Mass. Alternatively, any one of a number of other appropriate known devices for exciting gases remotely can be used. For example, inductively coupled plasma generation (e.g., RF plasma) may be used, wherein a chamber is wrapped with a coil through which current is passed. The gas to be excited is also inputted to the chamber as the current is being passed through the coil, which inductively generates a plasma by electromagnetically exciting the gas. Similarly, magnetically coupled plasma generation may be performed wherein electromagnets are used to electromagnetically couple to the gas to form a plasma.

A programmed controller 57 controls and coordinates the operation of chamber 40, vacuum pump 24, pulse valve 44 and heating of the susceptor 12 to achieve the operation which will now be described. A memory (not shown) within the controller 57 stores computer-readable instructions which cause the controller 57 to operate the system as described in the next section. It should be noted that the apparatus described above should in no way be construed as limiting the processes described herein, as the inventive processes can be carried out with various other apparatus.

A substrate 13 having a metallic layer deposited thereon is fed into chamber 10 by a robot blade (not shown) through a slit valve (not shown) in the wall of chamber 10 under transfer pressure. Lift pins (not shown) may pass through lift pin holes (not shown) in the susceptor 12 to facilitate the transfer of substrates into and out of the chamber 10, as known in the art.

The metallic layer on the substrate may be a film of tantalum, tantalum nitride, tungsten, tungsten nitride or titanium nitride, for example. The metallic layer is deposited, prior to the above-described loading into chamber 10, and may be accomplished by CVD, PECVD, PVD or other methods known in the art.

Once the substrate is positioned on the susceptor and the susceptor is in the processing position, chamber 10 is then pumped down to about 1-2 Torr and the chamber 10 and substrate 13 are brought within a temperature range of about 300-425° C. to ready the chamber for processing.

Next, a source gas containing nitrogen (e.g., N₂ or NH₃) is flowed into the chamber 40 through pulse valve 44 and converted to active nitrogen species by generating a plasma as described above, with microwave power being in the range of about 1400-4500 Watts. The activated nitrogen species are then flowed into chamber 10 through port 46 and allowed to pass over the surface of the metallic layer, where it reacts with the metal ions on the surface of the metallic layer to form a nitridated surface. The activated nitrogen species are flowed into chamber 10 at a flow rate of about 0.5-2 slm. An argon or helium carrier gas may also be flowed with the activated species, at a rate of about 1-2 slm, to prevent recombination of the activated nitrogen species. The flow rates are such to maintain a pressure of about 1-2 Torr in the chamber 10 during processing, at a temperature of about 300-425° C. These parameters can be adjusted, however, on the basis of empirical results, if required, to yield optimum results. It should be further noted, that the process temperature range is dependent upon the thermal budget of the device which is being treated. For example, for a tungsten, tantalum nitride or titanium nitride layer being treated by a nitridation process according to the present invention, in a front end of the line application, the temperature range could run from about 600-900° C. However, for a back end of the line application, the thermal budget is lower and the processing temperature must generally remain less than or equal to about 450° C. IN general, a ratio of N₂ to argon or helium carrier gas should be from about 1:1 to 1:2, with the flows being maintained to establish a pressure of about 1-2 Torr.

The activated nitrogen, in the case where a tungsten layer has been previously deposited, reacts with the surface layer to form tungsten nitride. The nitridated layer is very thin, having an average thickness of less than about 10 angstroms. By keeping the nitridated layer thin, the conductivity of the metallic layer is maximized, since the conductivity of the metal is higher than that of the nitridated metal.

Standard, well known, process conditions may be used to deposit the thin metallic film prior to flowing the activated nitrogen into the chamber to react with the surface of the thin metallic film. Thus, although one example of depositing a thin metallic film by CVD is described above, it is noted that the present invention is not to be limited to such a method of deposition of the thin metallic layer. For example, the thin metallic layer may be deposited according to other known techniques such as PVD, PECVD, rapid thermal processing., or the like.

In examples where an alternative process (other than CVD or RTPCVD) is used to deposit the metallic layer, the substrate, upon completion of the deposition, may be mounted in a system such as that shown in FIG. 1 to perform the nitridation step. Alternatively, the chamber used to perform the alternative method of metallic layer deposition may be modified to include a remote plasma chamber.

By moving the source of activated nitrogen to a remote plasma chamber, the chemistry can be controlled over a much broader range of operating and process conditions. In addition, keeping the activation step separate from the deposition step insures that a very thin surface layer can be grown as the nitridated layer. That is, the nitrogen is not allowed to react within the metallic layer, but only on the surface. That is, by separating the nitrogen plasma, the generation of activated nitrogen species above the substrate is prevented during the deposition of the metallic layer. A wider range of process conditions are also available for conducting the deposition phase of the metallic layer, due to the remote plasma generation.

FIG. 2 shows a partial sectional view of a stack assembled, which is representative of a capacitor structure, for example. The stack 60 includes layer 62 which could be silicon, for example, in the case of wafer processing. A thin insulative layer 64, such as SiO₂ is formed over layer 62 to act as a barrier between layer 62 and the bottom electrode layer 66 to be formed thereover. The bottom electrode 66, in this case is formed of tungsten and is deposited by any of the techniques described above. Tungsten is particularly advantageous where the electrode will be exposed to high temperature processing, although the present invention is applicable to any electrode material that forms an unstable oxide or a parasitic oxide upon deposition of a dielectric thereover. To enhance the stability of a dielectric layer interface with the bottom electrode, a barrier layer 66′ comprising tungsten nitride is created according to the process described above. Next a dielectric layer 68 is deposited over the nitridated bottom electrode. In this case the dielectric layer is tantalum oxide (i.e., Ta₂O₅) and is deposited by CVD, although other dielectric materials, such as hafnium oxide or zirconium oxide, or other dielectric oxide, for example, and/or processes may be used to establish the dielectric layer. Tantalum oxide (Ta₂O₅) is a useful material in the production of memory capacitors because, with a k value of 25, it provides a potential 4-to-6 fold increase in capacitance over silicon oxide, depending on the barrier material scheme that is used.

The nitridated surface of the tungsten electrode improves the adhesion between the tantalum oxide layer and the bottom electrode, thereby improving the overall stability and reliability of the entire structure. Temperature stability is also improved. Another barrier layer 70 may be formed on top of the dielectric layer 68 to prevent migration problems between the dielectric layer 68 and the top electrode layer 72 to be deposited thereon. For example, a nitride layer or oxide layer may be deposited over the dielectric layer 68. The top electrode layer is a metallic layer, although usually not tungsten, but another material, such as one comprising titanium or tantalum, e.g, titanium nitride or tantalum nitride, for example. The top electrode can be a formed by depositing a metal film, such as titanium (Ti), titanium nitride (TiN), or tantalum (Ta) or tantalum nitride (TaN) over the dielectric layer 68 (or barrier layer overlying dielectric layer 68, when a barrier layer is used), and then using well known photolithography and etching techniques to pattern the electrode film and dielectric layer, see for example, U.S. Pat. No. 6,204,203.

FIG. 4 is a schematic sectional representation of a front end DRAM/e-DRAM capacitor cell 200, which this case, like in the stack of FIG. 2, is formed of tungsten and is deposited by any of the techniques described above. To enhance the stability of a dielectric layer interface with the bottom electrode, a barrier 66′ comprising tungsten nitride is created according to the process described above. Next a dielectric layer 68 is deposited over the nitridated bottom electrode. In this case the dielectric layer is tantalum oxide (i.e., Ta₂O₅) and is deposited by CVD, although other dielectric materials and or processes may be used to establish the dielectric layer. Another barrier layer 70 may be formed on top of the dielectric layer 68 to prevent migration problems between the dielectric layer 68 and the top electrode layer 72 to be deposited thereon. The top electrode layer 72 is a metallic layer, although usually not tungsten, but another material, such as one comprising titanium or tantalum, e.g., titanium nitride or tantalum nitride.

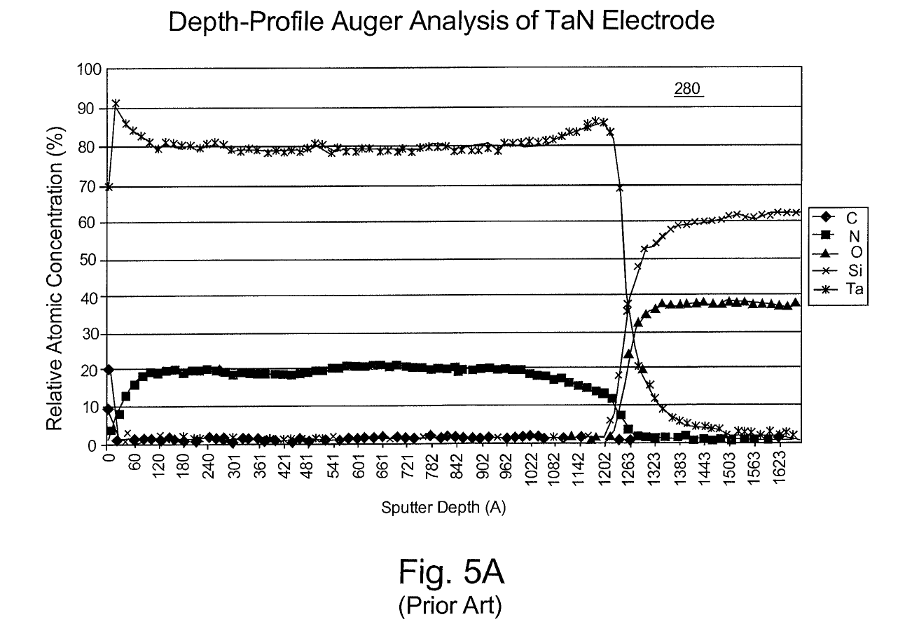

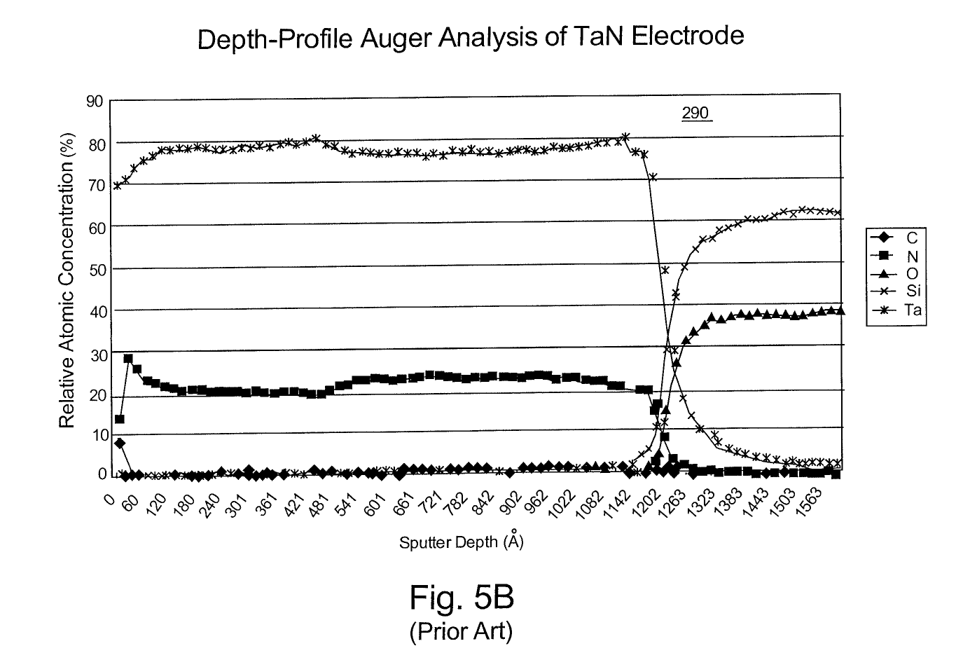

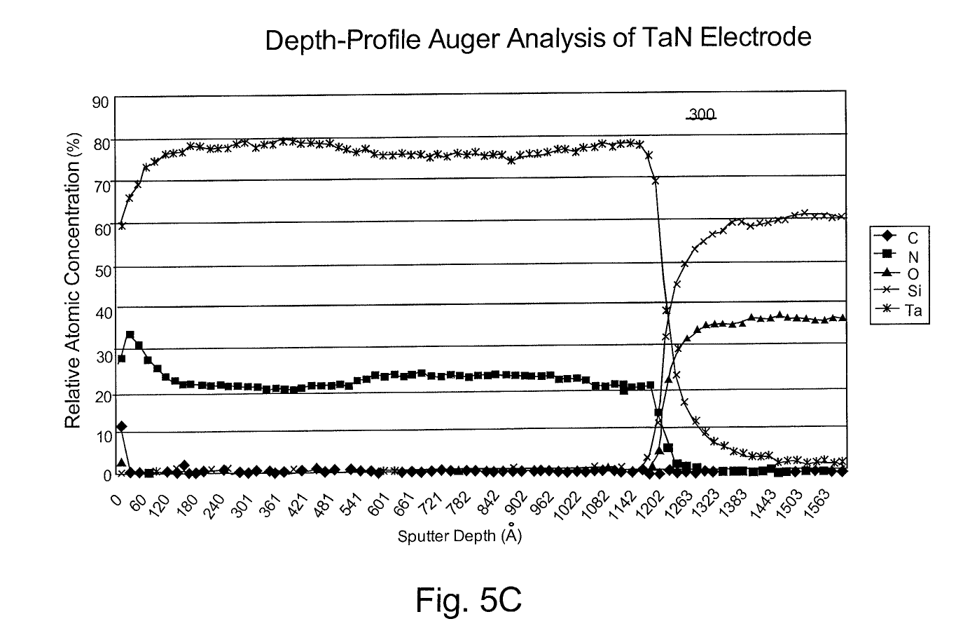

The graph in FIG. 5A shows the relative atomic concentration of the various atomic species at indicated depths of a TaN electrode layer produced according to a known method. In this method, the TaN layer was deposited by a conventional PVD technique. At a predetermined time before the end of the deposition process, typically 2 seconds, the nitrogen source was turned off, so that nitrogen no longer fed into the chamber, while the other precursor materials continued to be fed in and react to finish the deposition. This technique results in a top surface of the layer that has almost no nitrogen, e.g., about 3%, as seen at the left side of the graph. A surface with such a high purity of Ta will tend to react with a tanatalum oxide dielectric, as noted above.

The graph in FIG. 5B shows the results of a modified known process, which is used to deposit a TaN electrode layer. This process is essentially the same as that process described with regard to FIG. 5A, except that the nitrogen input is not shut off prior to completion of deposition of the layer. As a result, the top surface of the layer has a higher percentage of nitrogen than that shown in FIG. 5A, e.g., about 14%, as seen at the left side of the graph. However, the Ta/N ratio is still fairly high and this layer will also perform in a substandard fashion compared to the present invention.

FIG. 5C shows the relative atomic concentration of the various atomic species at indicated depths of a TaN electrode layer produced according to the present invention. The TaN layer may be deposited similarly to that described above with regard to FIG. 5B. Additionally, after deposition of the layer, a remote nitridation process is conducted as has been described above. As can be seen, the top surface of the layer resulting from these procedures has a much higher percentage of nitrogen than that shown in FIG. 5A or FIG. 5B, e.g., about 28%, as seen at the left side of the graph. Consequently, the Ta/N ratio at the surface is much greater than the previous two examples, i.e., 59/28 vs. 70/14 vs. 69/3.

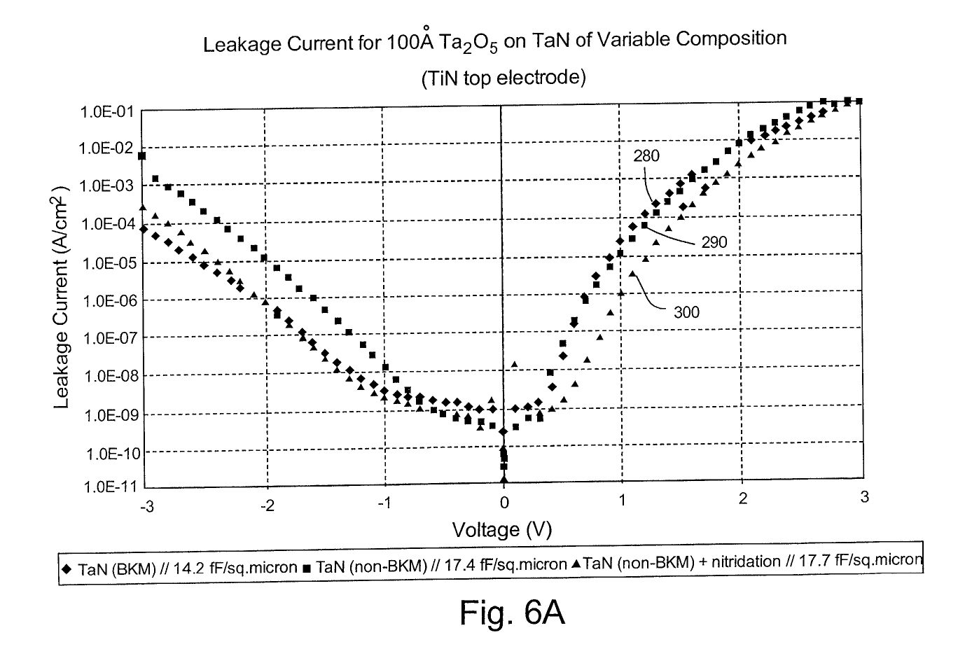

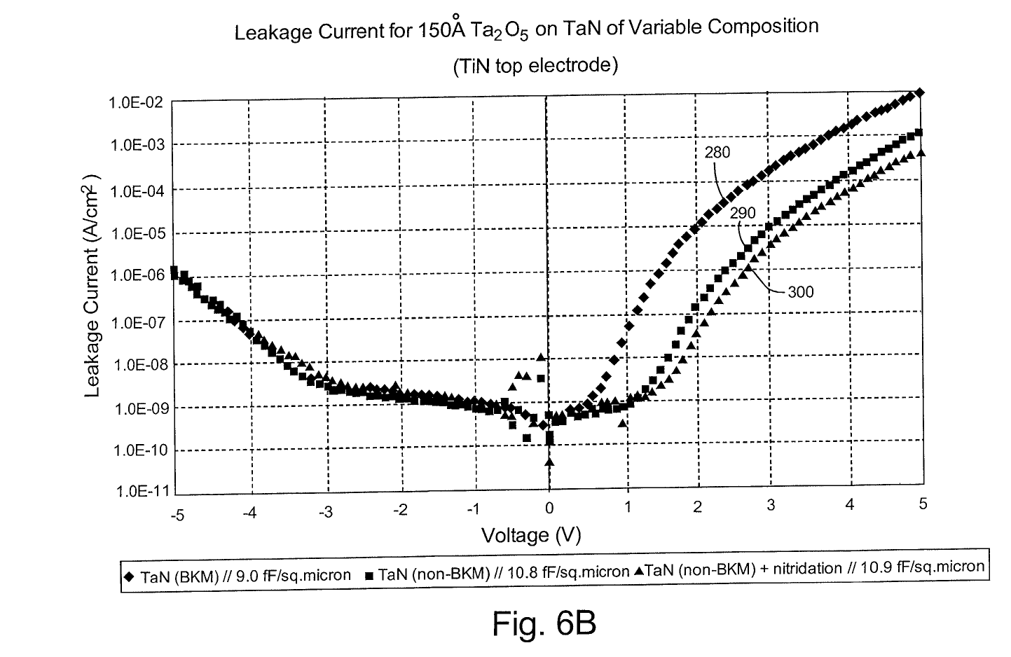

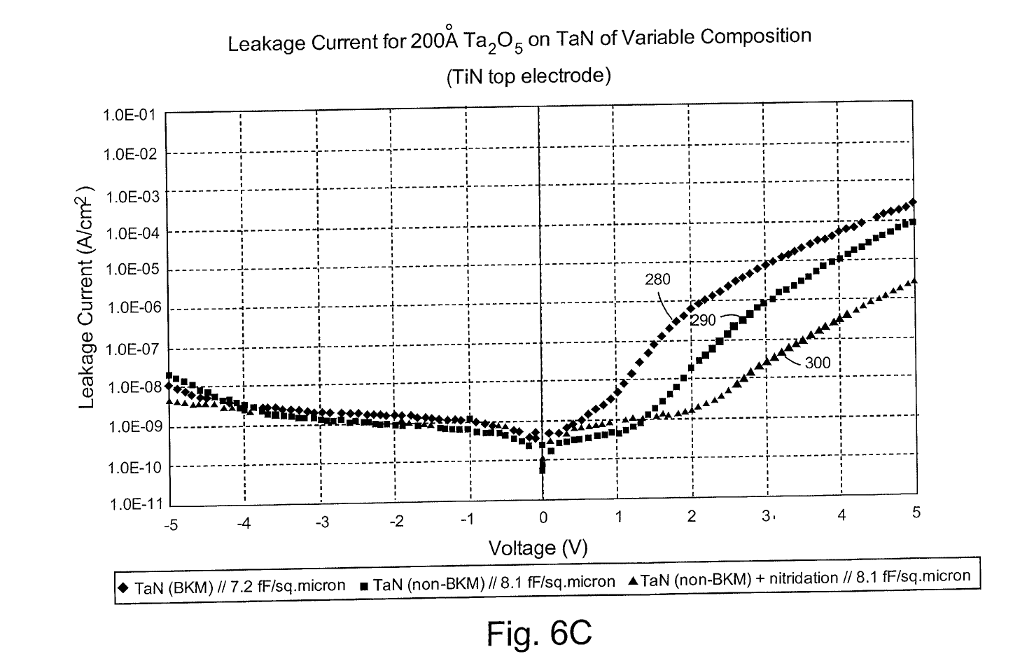

FIG. 6A contains plots which show by comparison the reduction in leakage current which is achieved by bottom electrodes made according to the present invention, as compared to those formed by the prior art processes described with regard to FIGS. 5A and 5B above. FIG. 6A plots leakage current at various voltages that are applied to capacitors having a TaN bottom electrode produced according to the method described with regard to FIG. 5A, i.e., plot 280; a TaN bottom electrode produced according to the method described with regard to FIG. 5B, i.e., plot 290; and a TaN bottom electrode produced according to the present invention, including remote nitridation; i.e. plot 300. Each capacitor also had a Ta₂O₅ dielectric layer having a thickness of about 100 Å and a TiN top electrode.

The capacitor having a bottom electrode 280 has a relatively low capacitance value of about 14.4 fF/μ² due to the interactivity (e.g., oxygen scavenging, parasitic capacitance) between the bottom electrode having a high Ta/N ration and the dielectric.

The capacitor having a bottom electrode 290 has an improved capacitance value of about 17.4 fF/μ², but little improvement in leakage current values on the positive side of the voltage scale. The capacitor having a bottom electrode 300 produced according to the present invention has the highest capacitance value of about 17.7 fF/μ², due to the least amount of oxygen scavenging and parasitic capacitance. Also, a significant decrease in leakage current is evidenced.

FIGS. 6B and 6C show similar results in capacitors which vary only in the thickness of the dielectric layer, respectively. FIG. 6B plots leakage current at various voltages that are applied to capacitors having a TaN bottom electrode produced according to the method described with regard to FIG. 5A, i.e., plot 280; a TaN bottom electrode produced according to the method described with regard to FIG. 5B, i.e., plot 290; and a TaN bottom electrode produced according to the present invention, including remote nitridation; i.e. plot 300. Each capacitor also had a Ta₂O₅ dielectric layer having a thickness of about 150 Å and a TiN top electrode. FIG. 6C plots leakage current at various voltages that are applied to capacitors having a TaN bottom electrode produced according to the method described with regard to FIG. 5A, i.e., plot 280; a TaN bottom electrode produced according to the method described with regard to FIG. 5B, i.e., plot 290; and a TaN bottom electrode produced according to the present invention, including remote nitridation; i.e. plot 300. Each capacitor also had a Ta₂O₅ dielectric layer having a thickness of about 200 Å and a TiN top electrode.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto.

That which is claimed is:

1. A method of treating a conductive surface to be used in making a stable conductor/dielectric interface, said method comprising the steps of:
providing a conductive substrate having a surface in a treatment chamber;
generating a nitrogen containing plasma in a cavity remote from the treatment chamber;
flowing a nitrogen reactive species created from the nitrogen containing plasma into the treatment chamber and over the surface of the conductive substrate; and
allowing the nitrogen reactive species to react with the surface of the conductive substrate to transform at least a portion of the surface into a nitride composition.

2. The method of claim 1, wherein the conductive substrate comprises tungsten and the surface is transformed into tungsten nitride.

3. The method of claim 2, wherein the conductive substrate comprises a tungsten film on a top surface thereof.

4. The method of claim 1, wherein the conductive substrate comprises a tungsten nitride film on a top surface thereof.

5. The method of claim 1, wherein the conductive substrate comprises a tantalum film on a top surface thereof.

6. The method of claim 1, wherein the conductive substrate comprises a tantalum nitride film on a top surface thereof.

7. The method of claim 1, wherein the conductive substrate comprises a titanium nitride film on a top surface thereof.

8. A method of forming a metal/dielectric stack structure, said method comprising the steps of:
depositing a metal film on a substrate;
generating a nitrogen containing plasma in a cavity remote from a treatment chamber in which the metal layer resides;
flowing a nitrogen reactive species created from the nitrogen containing plasma into the treatment chamber and over a surface of the metal layer, thereby reacting the nitrogen reactive species on the surface to form a nitridated surface; and
depositing a dielectric layer over the nitridated surface.

9. The method of claim 8, wherein said depositing a metal layer comprises depositing a tungsten film.

10. The method of claim 8, wherein said depositing a metal layer comprises depositing a tungsten nitride film.

11. The method of claim 8, wherein said depositing a metal layer comprises depositing a tantalum film.

12. The method of claim 8, wherein said depositing a metal layer comprises depositing a tantalum nitride film.

13. The method of claim 8, wherein said depositing a metal layer comprises depositing a titanium nitride film.

14. The method of claim 8, wherein said nitrogen containing plasma is generated from N₂ or NH₃.

15. A method of forming a nitridated surface on an electrically conductive substrate, said method comprising the steps of:
providing an electrically conductive substrate in a reaction chamber, said electrically conductive substrate having a surface;
generating a nitrogen containing plasma in a cavity remote from the reaction chamber;
flowing a nitrogen reactive species created from the nitrogen containing plasma into the reaction chamber and over the surface of the electrically conductive substrate, thereby reacting the nitrogen reactive species on the surface to form a nitridated surface.

16. The method of claim 15, wherein said electrically conductive substrate comprises a film of material selected from the group consisting of tungsten, tungsten nitrides, tantalum, tantalum nitrides and titanium nitrides, said film of material having been deposited over a semiconductor substrate.

17. The method of claim 16, wherein the semiconductor substrate comprises a silicon substrate and an oxide barrier layer interfacing with the film of material.

18. The method of claim 15, wherein said flowing is conducted for a period sufficient to establish said nitridated surface to a depth of less than about 10 angstroms.

19. A capacitor forming method comprising the steps of:
depositing an electrically conductive film on a substrate, thereby forming a bottom electrode;
generating a nitrogen containing plasma in a cavity remote from the bottom electrode; and
flowing a nitrogen reactive species, created from the nitrogen containing plasma, over at least a surface of the bottom electrode, thereby reacting the nitrogen reactive species with the electrically conductive film to form a nitridated surface on the electrically conductive film.

20. The method of claim 19, further comprising the step of depositing a dielectric layer over the nitridated bottom electrode.

21. The method of claim 20, wherein the dielectric material comprises Ta₂O₅.

22. The method of claim 19, wherein said electrically conductive film comprises a material selected from the group consisting of tungsten, tungsten nitrides, tantalum, tantalum nitrides and titanium nitrides.

23. A metallic layer deposited on a substrate in a semiconductor device, said metallic layer consisting essentially of tungsten and having a tungsten nitride surface.

24. The metallic layer of claim 22, wherein said tungsten nitride surface has a depth of less than about 10 angstroms.

25. A metallic layer deposited on a substrate in a semiconductor device, said metallic layer consisting essentially of tungsten nitride and having a surface having been further nitridated by remote plasma activation.

26. A metallic layer deposited on a substrate in a semiconductor device, said metallic layer consisting essentially of tantalum and having a tantalum nitride surface.

27. A metallic layer deposited on a substrate in a semiconductor device, said metallic layer consisting essentially of tantalum nitride and having a surface having been further nitridated by remote plasma activation.

28. A metallic layer deposited on a substrate in a semiconductor device, said metallic layer consisting essentially of titanium nitride and having a surface having been further nitridated by remote plasma activation.

29. A capacitor structure in a semiconductor device, said capacitor structure comprising:
a substrate;
a bottom electrode deposited on said substrate, said bottom electrode having an upper nitridated surf ace;
a dielectric layer deposited over said upper nitridated surface; and a top electrode deposited over said dielectric layer.

30. The capacitor structure of claim 29, wherein said dielectric layer comprises Ta₂O₅.

31. The capacitor structure of claim 29, further comprising a barrier layer deposited on a top surface of said dielectric layer and underlying said top electrode.

32. The capacitor structure of claim 29, wherein said bottom electrode comprises tungsten.

33. The capacitor structure of claim 29, wherein said bottom electrode comprises tantalum.

34. The capacitor structure of claim 29, wherein said bottom electrode comprises a material selected from the group consisting of tungsten, tungsten nitrides, tantalum, tantalum nitrides and titanium nitrides, and said upper nitridated surface having been formed by remote plasma activation.
